(19) United States
(12) Patent Application Publication
(10) Pub. No.: US 2026/0020324 A1
(43) Pub. Date: Jan. 15, 2026

(54) POWER SEMICONDUCTOR WITH SCHOTTKY CONTACT STRUCTURE

(71) Applicant: Magnachip Semiconductor, Ltd., Cheongju-si (KR)

(72) Inventors: Ki Hwan KIM, Seoul (KR); Ji Yong LIM, Seoul (KR); Chan Ho PARK, Seoul (KR); Su Young MOON, Gwacheon-si (KR); Seong Chan JEON, Gumi-si (KR); Jin Seong HAN, Seoul (KR); Ki Tae KANG, Gumi-si (KR); Jae Hyeon JUNG, Gumi-si (KR)

(73) Assignee: Magnachip Semiconductor, Ltd., Cheongju-si (KR)

(21) Appl. No.: 19/185,018

(22) Filed: Apr. 21, 2025

(30) Foreign Application Priority Data
Jul. 15, 2024 (KR) 10-2024-0093320

(51) Int. Cl. H10D 84/00; H10D 8/01; H10D 8/60; H10D 30/01; H10D 30/63; H10D 62/10

(52) U.S. Cl. CPC H10D 84/101; H10D 8/60; H10D 30/63; H10D 62/107; H10D 62/124; H10D 8/051; H10D 30/025

(57) ABSTRACT

A power semiconductor with a Schottky contact structure includes gate regions spaced apart by a predetermined interval in a first direction; a highly doped source region of a first conductivity-type positioned between the gate regions; a source contact region disposed on the highly doped source region of the first conductivity-type; a plurality of buried pillar regions of a second conductivity-type spaced at a preset interval in a second direction intersecting the first direction; and Schottky contact regions formed at a point where the plurality of buried pillar regions of the second conductivity-type intersect with the gate regions.

### CROSS-REFERENCE TO RELATED APPLICATION

This application claims the benefit under 35 U.S.C. § 119 (a) of Korean Patent Application No. 10-2024-0093320, filed on Jul. 15, 2024, in the Korean Intellectual Property Office, the entire disclosure of which is incorporated herein by reference for all purposes.

### BACKGROUND

### 1. Field

The present disclosure relates to a power semiconductor device with a Schottky contact structure.

### 2. Description of Related Art

A super junction MOSFET, a type of power semiconductor device, is used in various applications, for example, in various types of power supplies, such as DC-DC converters, inverters, and LLC converters. To apply this to such applications, it is important to secure a fast reverse recovery time (Trr). However, a super junction MOSFET (hereinafter referred to as a “power semiconductor device” or “semiconductor device”) has a relatively slow reverse recovery time due to the influence of a P-type pillar.

Various solutions have been proposed to improve this issue in the related art. For example, electron irradiation, particle irradiation (proton irradiation and other particle irradiations), etc. have been used to secure a fast reverse recovery time. However, these methods involve increase in process complexity, increased manufacturing costs, and problems such as increased leakage current and on-resistance (Rdson) in semiconductor devices, which in turn increases power consumption. There is also a method of connecting a separate fast recovery diode in reverse parallel, but this method requires the addition of the fast recovery diode element in the package, which increases the package volume and manufacturing costs.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a semiconductor device includes: a plurality of gate regions spaced apart by a predetermined interval in a first direction; a highly doped source region of a first conductivity-type disposed between the plurality of gate regions; a source contact region disposed on the highly doped source region of the first conductivity-type; a plurality of buried pillar regions of a second conductivity-type spaced at a preset interval in a second direction intersecting the first direction; and a plurality of Schottky contact regions formed at a point where the plurality of buried pillar regions of the second conductivity-type intersect with the plurality of gate regions.

The power semiconductor device may further include a body region of the second conductivity-type connected to the plurality of buried pillar regions of the second conductivity-type. The plurality of buried pillar regions of the second conductivity-type may be formed below the plurality of gate regions and the highly doped source region of the first conductivity-type.

An epitaxial layer of the first conductivity-type may be formed over the plurality of buried pillar regions of the second conductivity-type.

The first direction and the second direction may be orthogonal to each other.

A plurality of Schottky contact regions may be formed on one of the plurality of buried pillar regions of the second conductivity-type.

A plurality of Schottky contact regions may be formed in one of the plurality of gate regions.

At least one Schottky contact region may be formed in one of the plurality of gate regions.

At least one of the plurality of Schottky contact regions may extend in the second direction in which a buried pillar region of the second conductivity-type is not formed.

In another general aspect, a power semiconductor device includes a substrate of a first conductivity-type; an epitaxial layer of the first conductivity-type formed on the substrate of the first conductivity-type; a plurality of buried pillar regions of a second conductivity-type formed within the epitaxial layer of the first conductivity-type; a body region of the second conductivity-type formed at a predetermined depth from an upper surface of the epitaxial layer of the first conductivity-type and connected to the plurality of buried pillar regions of the second conductivity-type; a highly doped source region of the first conductivity-type formed in the body region of the second conductivity-type; a source contact region formed on the body region of the second conductivity-type; a plurality of gate regions formed between body regions of the second conductivity-type; and a plurality of Schottky contact regions formed in portions of the plurality of gate regions.

The plurality of Schottky contact regions may be formed in a region where the plurality of buried pillar regions of the second conductivity-type and the plurality of gate regions intersect.

The plurality of buried pillar regions of the second conductivity-type and the plurality of gate regions may intersect each other perpendicularly.

The plurality of Schottky contact regions and the source contact region may be connected to a source metal layer.

At least one of the plurality of Schottky contact regions may extend in a direction in which the plurality of buried pillar regions of the second conductivity-type are not formed.

An interlayer insulating film may be formed between the plurality of Schottky contact regions and the plurality of gate regions.

In another general aspect, a power semiconductor device includes a substrate of a first conductivity-type; an epitaxial layer of the first conductivity-type formed on the substrate of the first conductivity-type; a plurality of buried pillar regions of a second conductivity-type extending in a first direction, spaced apart in a second direction, and formed within the epitaxial layer of the first conductivity-type; a body region of a second conductivity-type formed on the plurality of buried pillar regions of the second conductivity-type; a source region of the first conductivity-type formed within the body region of the second conductivity-type; a source contact region formed on the body region of the first conductivity-type; a plurality of gate regions formed on the epitaxial layer of the first conductivity-type; and a plurality of Schottky contact regions formed in portions of the plurality of gate regions. The body region of the second conductivity-type may intersect the plurality of buried pillar regions of the second conductivity-type.

The plurality of buried pillar regions of the second conductivity-type may simultaneously contact the body region of the second conductivity-type and the epitaxial layer of the first conductivity-type.

The plurality of buried pillar regions of the second conductivity-type and the plurality of gate regions may be orthogonal to each other.

The plurality of buried pillar regions of the second conductivity-type may intersect perpendicularly with the body region of the second conductivity-type.

At least one of the plurality of Schottky contact regions may extend in the first and second directions and contact the epitaxial layer of the first conductivity-type.

A width of the body region of the second conductivity-type may be less than a width of a buried pillar region of the second conductivity-type.

Other features and aspects will be apparent from the following detailed description, the drawings, and the claims.

### BRIEF DESCRIPTION OF THE DRAWINGS

FIGS. 1A and 1B illustrate a cross-sectional view and a plan view, respectively, of a power semiconductor according to the related art for comparison with the present disclosure.

FIG. 2A illustrates a plan view of a power semiconductor according to an example of the present disclosure.

FIGS. 2B, 2C, and 2D illustrate plan views of a power semiconductor according to another example of the present disclosure.

FIG. 3 illustrates a cross-sectional view taken along line A-A′ of FIG. 2A.

FIG. 4 illustrates a cross-sectional view taken along line B-B′ of FIG. 2A.

FIG. 5 illustrates a cross-sectional view taken along line C-C′ of FIG. 2A.

FIG. 6 illustrates a cross-sectional view taken along line D-D′ of FIG. 2A.

FIG. 7 illustrates a flowchart illustrating a method of manufacturing a power semiconductor device according to an example of the present disclosure.

FIG. 8 illustrates a graph comparing the turn-on and turn-off states of reverse bias injection in the power semiconductor structures of the present disclosure and the related art.

Throughout the drawings and the detailed description, unless otherwise described, the same reference numerals refer to the same elements. The drawings may not be to scale, and the relative size, proportions, and depiction of elements in the drawings may be exaggerated for clarity, illustration, and convenience.

### DETAILED DESCRIPTION

Hereinafter, while examples of the present disclosure will be described in detail with reference to the accompanying drawings, it is noted that examples are not limited to the same.

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness, noting that omissions of features and their descriptions are also not intended to be admissions of their general knowledge.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application. The use of the term “may” herein with respect to an example or embodiment, e.g., as to what an example or embodiment may include or implement, means that at least one example or embodiment exists where such a feature is included or implemented, while all examples are not limited thereto.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes shown in the drawings may occur. Thus, the examples described herein are not limited to the specific shapes shown in the drawings, but include changes in shape that occur during manufacturing.

The features of the examples described herein may be combined in various ways as will be apparent after an understanding of the disclosure of this application. Further, although the examples described herein have a variety of configurations, other configurations are possible as will be apparent after an understanding of the disclosure of this application.

The objective of the present disclosure is to provide a power semiconductor device capable of providing a fast reverse recovery time (Trr) without incurring significant additional costs, thereby solving the problems described above.

Another objective of the present invention is to provide a power semiconductor device that prevents a degradation in device performance due to an increase in on-resistance (Rdson).

The technical problems of the present disclosure are not limited to the technical problems mentioned above, and other unmentioned technical problems will be clearly understood by those skilled in the art from the description provided below.

A detailed description is given below, with reference to attached drawings.

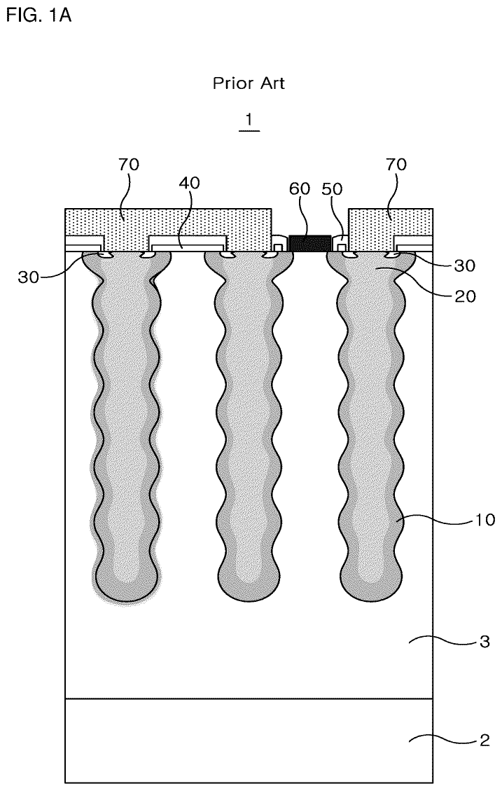

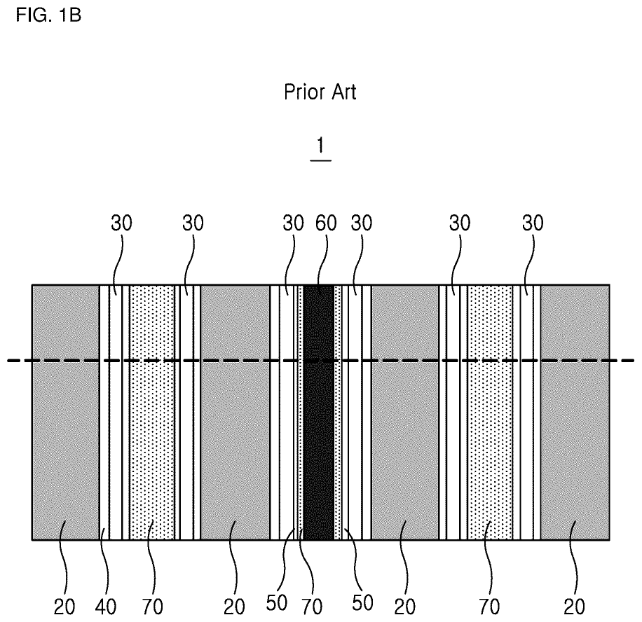

FIGS. 1A and 1B illustrate a cross-sectional view and a plan view, respectively, of a power semiconductor according to the related art for comparison with the present disclosure.

Referring to FIGS. 1A and 1B, a power semiconductor 1 has a structure in which a P-type pillar 10 and a gate region (or gate poly region) 40 are disposed parallel to each other. Specifically, a first conductivity-type (e.g., N-type) substrate 2 is provided and a first conductivity-type epitaxial layer 3 are formed on the first conductivity-type substrate 2. In the first conductivity-type epitaxial layer 3, a plurality of pillar regions 10 of a second conductivity type (e.g., P-type) are formed at predetermined intervals.

On the pillar region 10 of the second conductivity type, a body region 20 is formed. Within the body region 20, a first conductivity-type highly doped source region 30 is formed. On the body region 20 and the first conductivity-type highly doped source region 30, a gate region 40 is formed. On the gate region 40, a source contact region 70 is formed.

The source contact region 70 may be formed of an aluminum (Al) metal layer.

In addition, the power semiconductor 1 includes a dummy gate region 50. The dummy gate region 50 is disposed between the gate regions 40. Additionally, a metal layer is formed on the second conductivity-type pillar region 10 between the dummy gate regions 50 and on the first conductivity-type epitaxial layer 3 between the second conductivity-type pillar regions 10. The region where the metal layer is formed becomes the Schottky contact region 60.

That is, the conventional power semiconductor structure reduces hole current and, consequently, the reverse recovery time by adding the Schottky contact region 60 to the second conductivity-type pillar region 10 without incurring additional process costs. However, the conventional structure leads to a reduction in the N-type channel due to the decrease in the gate region 40. Moreover, as the cell pitch decreases, the N-type channel proportionally decreases. If the N-type channel is completely eliminated, the on-resistance Rdson increases, potentially degrading device performance.

As shown in the conventional structures of FIGS. 1A and 1B, the Schottky contact region 60 was used to reduce the reverse recovery time. However, this approach led to an increase in the on-resistance Rdson characteristics.

Accordingly, there is a need for a solution that reduces the reverse recovery time without increasing the on-resistance characteristics. The present disclosure proposes a power semiconductor device with such a structure. In the examples of the present disclosure described below, the first conductivity type is exemplified as N-type and the second conductivity type as P-type; however, the opposite configuration is also possible.

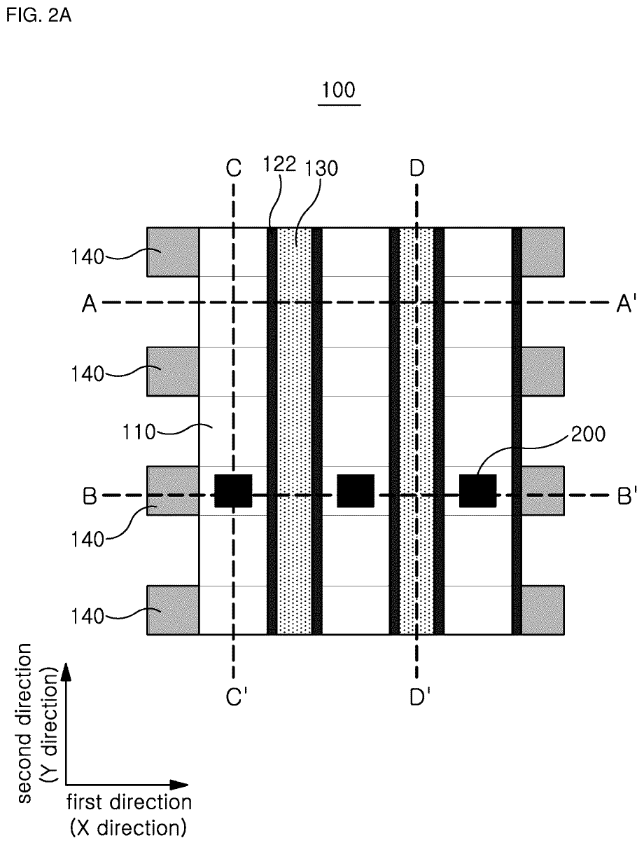

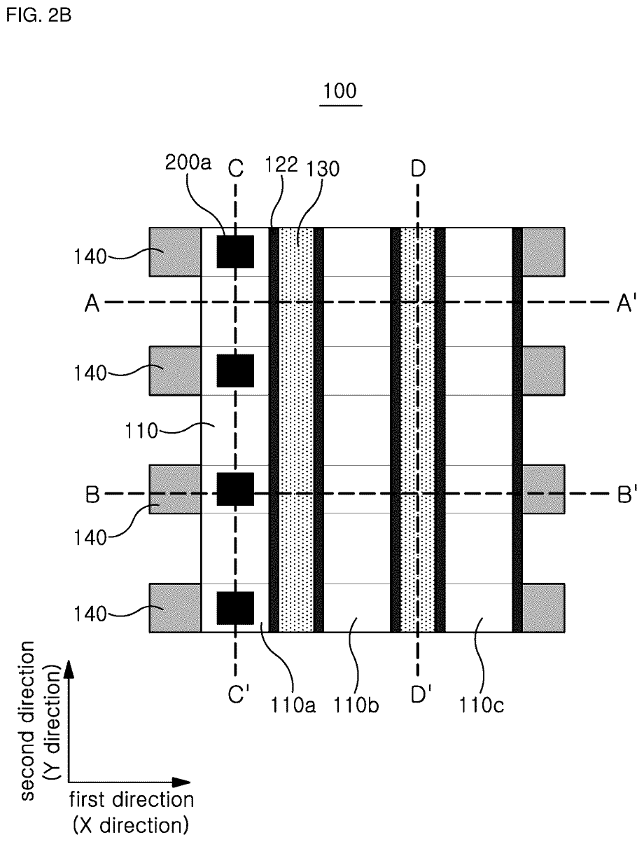

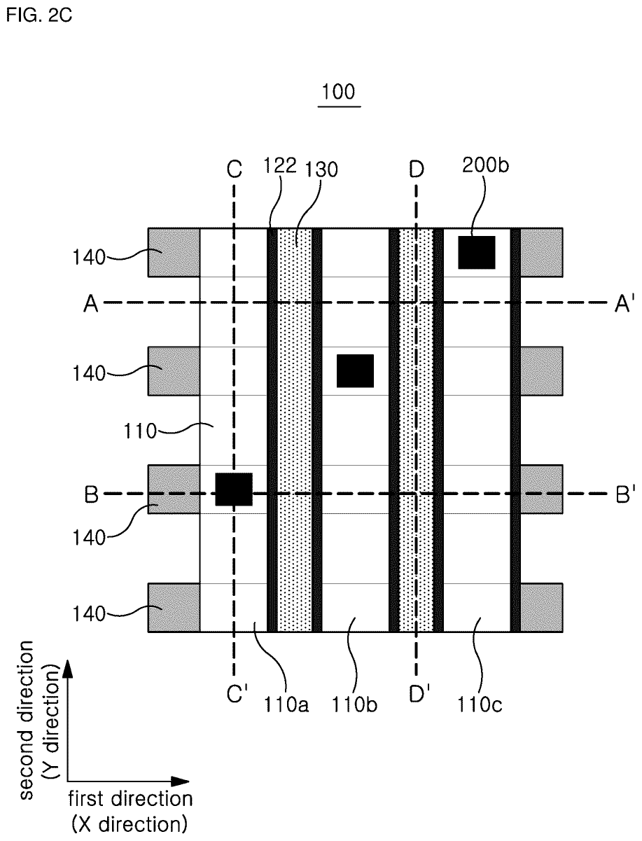

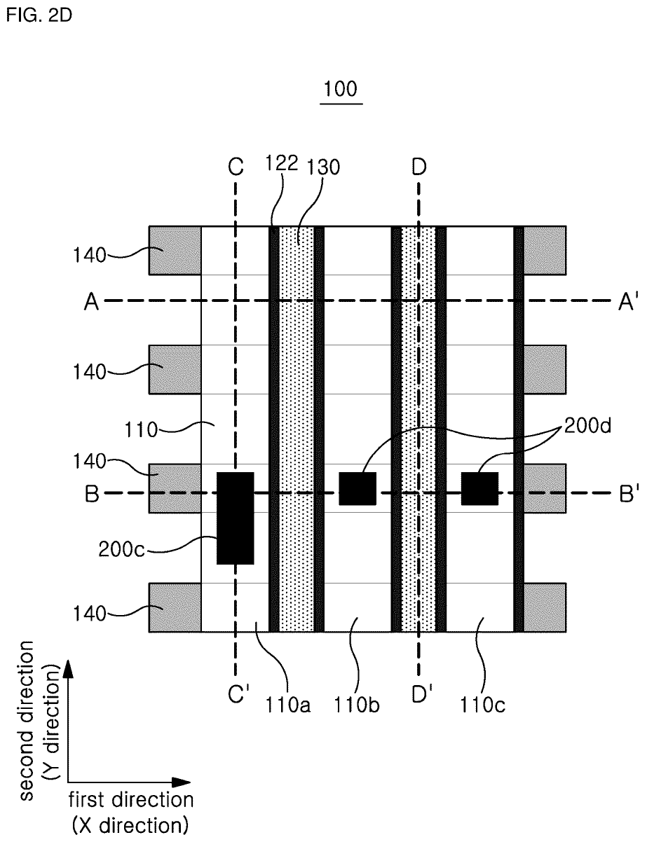

FIG. 2A illustrates a plan view of a power semiconductor according to an example of the present disclosure, and FIGS. 2B, 2C, and 2D illustrate plan views of a power semiconductor according to another example of the present disclosure.

Referring to FIG. 2A, a power semiconductor 100 includes a gate region 110, a first conductivity-type (e.g., N-type) highly doped source region 122, a source contact (ohmic contact) region 130, a second conductivity-type (e.g., P-type) buried pillar region 140, and a Schottky contact region 200. In this configuration, the second conductivity-type buried pillar region 140 and the gate region 110 are disposed orthogonally to each other. From a plan view perspective, the arrangement has a substantially grid-like pattern.

More specifically, the gate region 110 may be disposed, for example, as a first gate region 110a, a second gate region 110b, and a third gate region 110c, though this is not limited thereto, and a plurality of gate regions may be disposed. The gate regions 110a, 110b, 110c are disposed at a predetermined interval in a first direction (i.e., the horizontal direction and X direction), and between the gate regions 110a, 110b, 110c, the first conductivity-type highly doped source region 122 is disposed. Between the first conductivity-type highly doped source regions 122, the source contact region 130 is disposed.

The second conductivity-type buried pillar region 140 is disposed at a predetermined interval in a second direction (i.e., the vertical direction and Y direction) so as to be orthogonal to the gate regions 110a, 110b, 110c. In this configuration, the second conductivity-type buried pillar region 140 may be positioned beneath the gate regions 110a, 110b, 110c, as well as the first conductivity-type highly doped source region 122. Additionally, the Schottky contact region 200 is formed in a portion of the gate regions 110a, 110b, 110c that intersects with one of the second conductivity-type buried pillar regions 140, which are disposed at predetermined intervals in the vertical direction. In FIG. 2A, the Schottky contact region 200 is formed in the first direction for each of the gate regions 110a, 110b, 110c. In this configuration, the Schottky contact region 200 is formed on a portion of the gate region 110 line, thereby securing an N-type channel in the active region of the semiconductor device. This structure differs from the conventional structure described with reference to FIG. 1A and FIG. 1B, in which a dummy gate is formed between gate regions and a Schottky contact region 60 is formed between the dummy gates 50. According to the example, the Schottky contact region may be formed of a metal instead of polysilicon.

The second conductivity-type buried pillar region 140 may be disposed in multiple instances, and the Schottky contact region 200 may also be disposed in multiple instances.

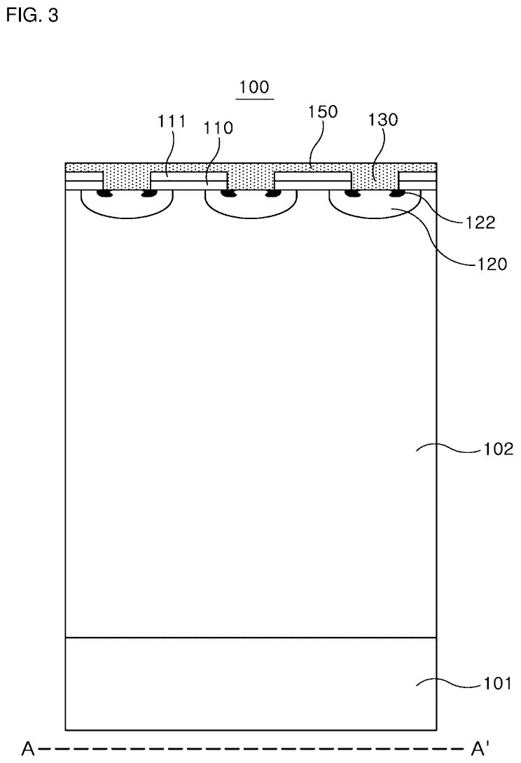

A second conductivity-type body region (not shown in FIG. 2A) is disposed beneath the gate region 110 (refer to FIG. 3).

The metal layer of the Schottky contact may be formed from materials such as tungsten (W), titanium (Ti), or titanium tungsten (Ti/W), which can reduce contact resistance and leakage current.

In FIGS. 2A and 2B, the gate regions 110a, 110b, 110c in the first direction, the first conductivity-type highly doped source region 122, and the source contact region 130, as well as the second conductivity-type buried pillar region 140 in the second direction, are disposed separately and alternately. This can be described as being formed in a staggered grid configuration.

Herein, with respect to the first direction, the width of the second conductivity-type buried pillar region 140 is greater than the width of the gate regions 110a, 110b, 110c.

In the plane, the first direction may be the X direction, and the second direction may be the Y direction.

Referring to FIG. 2B, the planar structure of the power semiconductor device according to another example of FIG. 2B is the same as that of FIG. 2A. However, the position where the Schottky contact region is formed is adjusted depending on the region where the gate is formed.

Specifically, when the gate regions are divided, they may be disposed as the first gate region 110a, the second gate region 110b, and the third gate region 110c. In the example of FIG. 2B, the Schottky contact region 200a is disposed at an interval in the second direction from the first gate region 110a, which is a distinguishing feature.

Referring to FIG. 2C, the planar structure of the power semiconductor device according to another example of FIG. 2C is the same as that of FIG. 2A, and the gate regions may also be disposed in the same manner as in FIG. 2A. In the example of FIG. 2C, a Schottky contact region 200b is disposed for each of the first gate region 110a, the second gate region 110b, and the third gate region 110c. For example, they may be spaced apart in a stepped arrangement.

Referring to FIG. 2D, the planar structure of a power semiconductor device according to another example of FIG. 2D is the same as that of FIG. 2A, and the gate regions may also be disposed in the same manner as in FIG. 2A. In the example of FIG. 2D, a Schottky contact region is disposed for each of a first gate region 110a, a second gate region 110b, and a third gate region 110c. In particular, a Schottky contact region 200c formed in the first gate region 110a may be disposed to extend in a second direction, and Schottky contact regions 200d of the second and third gate regions 110b and 110c may be disposed in the same manner as in the structure of FIG. 2A.

Herein, the length of the Schottky contact region 200c extending in the second direction, which is formed in the first gate region 110a, may be shorter than the length of the gate region in the second direction or shorter than the length of the source contact region. By arranging the Schottky contact region in various structures, as in the other examples of FIGS. 2B to 2D, a desired reverse recovery time may be achieved during reverse bias.

It is to be understood that the present disclosure is not limited to the Schottky contact region structures disposed in the examples of FIGS. 2B to 2D and may also be designed to be disposed in various other directions.

FIG. 3 illustrates a cross-sectional view taken along line A-A′ of FIG. 2A.

The cross-section along line A-A′ of FIG. 3 represents the cross-sectional structure of a line passing in the first direction from the planar view of FIG. 2A and may include the gate region 110, the first conductivity-type highly doped source region 122, the source contact region 130, and a body region 120. A source metal region 150 is formed on the source contact region 130. These components constitute the region where the power semiconductor device 100 operates. Herein, the second conductivity-type body region 120 is connected to the second conductivity-type buried pillar region 140.

Specifically, the first conductivity-type substrate 101 is provided, and a first conductivity-type epitaxial layer 102 is formed on the first conductivity-type substrate 101. The second conductivity-type body region 120 is formed in the first conductivity-type epitaxial layer 102, and the first conductivity-type highly doped source region 122 is formed in the second conductivity-type body region 120. The second conductivity-type body region 120 and the first conductivity-type highly doped source region 122 may form a dual-injection MOSFET (DIMOSFET) structure, which is formed through an ion implantation process. Therefore, the cross-sectional structure of FIG. 3 may be referred to as a planar gate vertical MOSFET region.

The gate region 110 is formed in the substrate between the second conductivity-type body regions 120, and the gate region 110 is connected to the first conductivity-type highly doped source region 122. The gate region 110 has a gate insulating film (not shown) formed at the bottom, and an interlayer insulating film 111 formed at the top. Additionally, the source contact region 130 is formed over the gate region 110 and the second conductivity-type body region 120. Since the source contact region 130 is in contact with silicide, it is also referred to as an ohmic contact region.

The interlayer insulating film 111 may be formed in multiple layers.

A drain region (not shown) may be formed below the first conductivity-type substrate 101.

The source contact region 130 may be formed of tungsten or aluminum metal, and the source metal region 150 may be formed of aluminum.

The Schottky contact region 200 is formed along the second direction, and the source contact region 130 and the Schottky contact region 200 are interconnected with the source metal region 150.

In this drawing, the illustration is referenced with respect to the source metal region 150 layer.

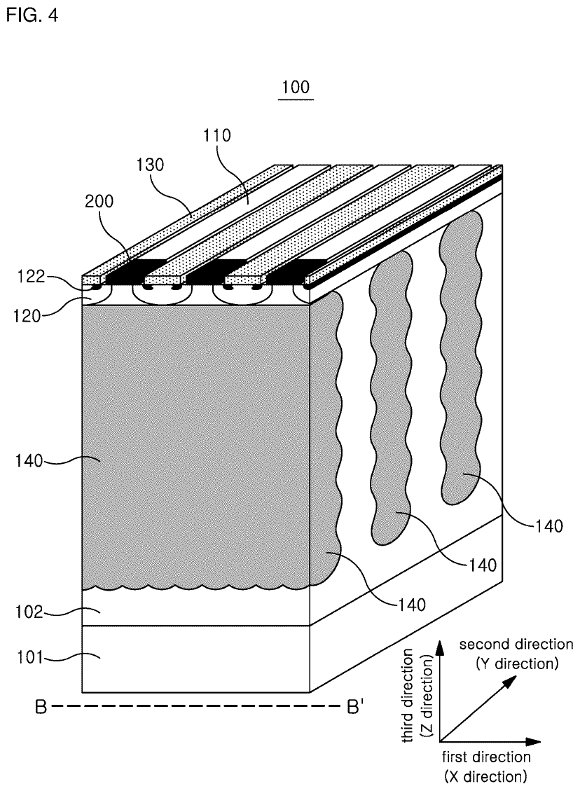

FIG. 4 illustrates a cross-sectional view taken along line B-B′ of FIG. 2A.

The cross-section along line B-B′ of FIG. 4 represents the cross-sectional structure of a line passing in the horizontal direction or first direction from the planar view of FIG. 2A, and may include the Schottky contact region 200, the source contact region 130, the second conductivity-type body region 120, the first conductivity-type highly doped source region 122, and the second conductivity-type buried pillar region 140. As previously described, the power semiconductor device 100 of this example secures an N-type channel by forming the Schottky contact region 200 only in certain areas between the second conductivity-type body regions 120 on the first conductivity-type epitaxial layer 102.

Specifically, a first conductivity-type substrate 101 is provided, and a first conductivity-type epitaxial layer 102 is formed on the first conductivity-type substrate 101. The second conductivity-type buried pillar region 140 is disposed within the first conductivity-type epitaxial layer 102. The second conductivity-type body region 120 is formed on the second conductivity-type buried pillar region 140, and the second conductivity-type buried pillar region 140 and the second conductivity-type body region 120 are connected to each other. This arrangement enables the achievement of a high breakdown voltage and low on-resistance for the semiconductor device 100. If the device is designed as a typical DMOS transistor without the formation of the second conductivity-type buried pillar region 140, the high breakdown voltage required for high-voltage semiconductor devices in this example of the power semiconductor 100 cannot be achieved.

The second conductivity-type buried pillar region 140, as seen in reference to FIG. 2A, extends along the first direction and is disposed with a spacing along the second direction. In the cross-sectional view of FIG. 4, it extends in a horizontal form within the first conductivity-type epitaxial layer 102 and may be formed with a spacing along the second direction.

The second conductivity-type buried pillar region 140 and the second conductivity-type body region 120 may be formed in a structure where they intersect and are disposed in relation to each other.

The width of the second conductivity-type body region 120, with respect to the first direction, may be disposed to be shorter than the width of the second conductivity-type buried pillar region.

Additionally, the first conductivity-type highly doped source region 122 is formed within the second conductivity-type body region 120, and the source contact region 130 is disposed on the first conductivity-type highly doped source region 122. The Schottky contact region 200 is formed between the second conductivity-type body regions 120. The Schottky contact region 200 is formed in direct contact with the upper surface of the second conductivity-type body region 120. The Schottky contact region 200 may also be referred to as a Schottky diode region, Schottky metal, or Schottky barrier diode (SBD).

In conventional Schottky diodes, the threshold voltage (Vt) is inherently low, and when an electric field is concentrated near the Schottky contact, leakage current is generated, which directly causes reliability issues in power semiconductor devices. Specifically, if leakage current occurs in the device, the lattice temperature may rise, which may cause the device to malfunction. Therefore, in the present disclosure, the orthogonal cell structure is applied to prevent the reduction of the gate region length, thereby maintaining a low on-resistance. In addition, the leakage current generated in the Schottky diode is mitigated by the second conductivity-type buried pillar region 140, which mitigates the electric field, thereby reducing leakage current, preventing device failure, and improving reliability.

The length of the Schottky contact region 200 in the second direction may be arranged to be shorter than the length of the gate region 110 and may also be arranged to be shorter than the length of the source contact region 130 in the second direction.

The source metal region 150 may be connected on the Schottky contact region 200 and the source contact region 130. In the present drawing, the illustration is based on the layers of the source contact region 130 and the Schottky contact region 200.

As described above, in the present disclosure, the second conductivity-type buried pillar region 140 and the gate poly 110 are formed in an orthogonal direction, while the Schottky contact region 200 is formed in a portion of the gate region 110. The second conductivity-type buried pillar region 140 is positioned below the Schottky contact region 200, thereby securing the N-type channel and reducing leakage current.

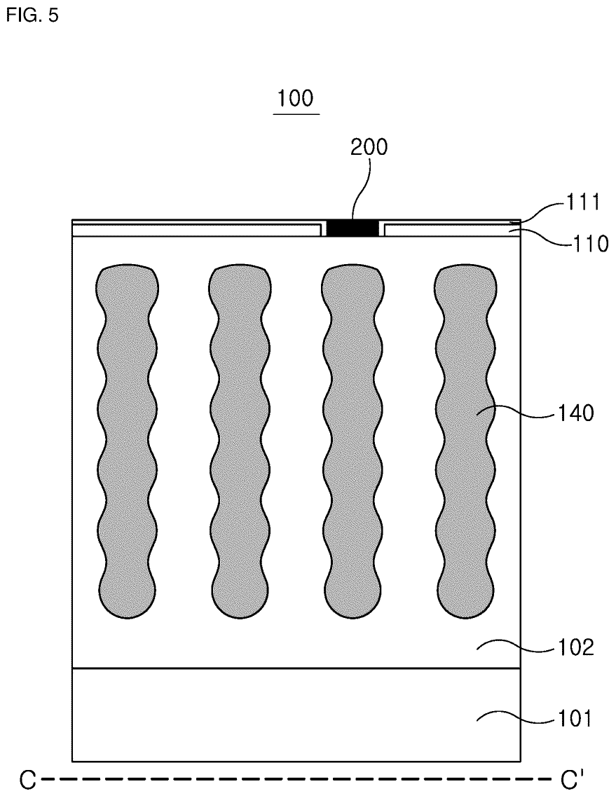

FIG. 5 illustrates a cross-sectional view along line C-C′ of FIG. 2A.

The cross-section along the line C-C′ of FIG. 5 represents the cross-sectional structure of a line passing in the second direction from the planar view of FIG. 2A, and may include the gate region 110, the Schottky contact region 200, and the second conductivity-type buried pillar region 140.

Specifically, a first conductivity-type substrate 101 is provided, and a first conductivity-type epitaxial layer 102 is formed on the first conductivity-type substrate 101. A second conductivity-type buried pillar region 140 is disposed within the first conductivity-type epitaxial layer 102. The second conductivity-type buried pillar region 140 is disposed in a structure where the regions are spaced apart from each other according to the direction of the cross-sectional view. Herein, the first conductivity-type epitaxial layer 102 may be formed through a multi-epitaxial layer process, and during the multi-epitaxial layer process, the second conductivity-type buried pillar region 140 may be formed through a multi-ion implantation process.

A gate region 110 is formed on the first conductivity-type epitaxial layer 102, extending in the second direction, and an interlayer insulating film 111 is formed on the gate region 110. Additionally, a Schottky contact region 200 is formed on the first conductivity-type epitaxial layer 102 corresponding to one of the second conductivity-type buried pillar regions 140. In the drawing, it can be seen that the Schottky contact region 200 is formed on a portion of the gate region 110 extending in the second direction.

In addition, the second conductivity-type buried pillar region 140 is arranged at intervals in the Y-direction, while the second conductivity-type body region 120 is arranged in the lateral direction, and a source contact region 130 is arranged on the second conductivity-type body region 120.

The Schottky contact region 200 refers to an area where Schottky metal is directly in contact with the first conductivity-type epitaxial layer 102. By arranging the Schottky contact region 200 between the gate regions 110, an N-type channel can be secured. Additionally, by adding the Schottky contact region 200 between each gate region 110, the hole current can be reduced when a reverse bias is applied to the semiconductor device 100, and furthermore, the reverse recovery time (Trr) of the semiconductor device 100 can be reduced, improving the turn-on and turn-off speeds of the semiconductor device 100.

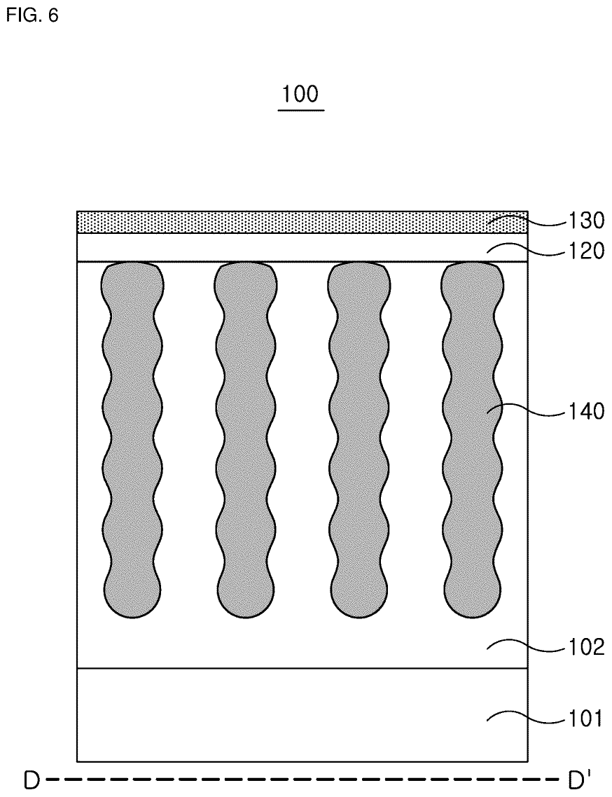

FIG. 6 illustrates a cross-sectional view along line D-D′ of FIG. 2A.

The cross-section along line D-D′ of FIG. 6 may include the source contact region 130, the second conductivity-type body region 120, and the second conductivity-type buried pillar region 140.

Specifically, a first conductivity-type substrate 101 is provided, and a first conductivity-type epitaxial layer 102 is formed on the first conductivity-type substrate 101. A second conductivity-type buried pillar region 140 is disposed within the first conductivity-type epitaxial layer 102. The second conductivity-type buried pillar region 140 is disposed in a spaced-apart structure. The first conductivity-type epitaxial layer 102 can be formed through a multi-epitaxial process, which forms multiple epitaxial layers on the substrate surface. During the multi-epitaxial process, a multi-ion implantation process can be used to implant second conductivity-type ions onto a single epitaxial layer, thereby forming the second conductivity-type buried pillar region 140.

Above the second conductivity-type buried pillar region 140, the second conductivity-type body region 120 and the source contact region 130 are sequentially stacked. The source contact region 130 is connected to the source contact region 130 in FIGS. 3 and 4, as previously described. Additionally, the second conductivity-type body region 120 is connected to the second conductivity-type body region in FIGS. 3 and 4.

According to the structure shown in FIG. 6, the power semiconductor device 100 of this example operates in a Super Junction MOSFET structure, thereby achieving a high breakdown voltage and low on-resistance (Rdson).

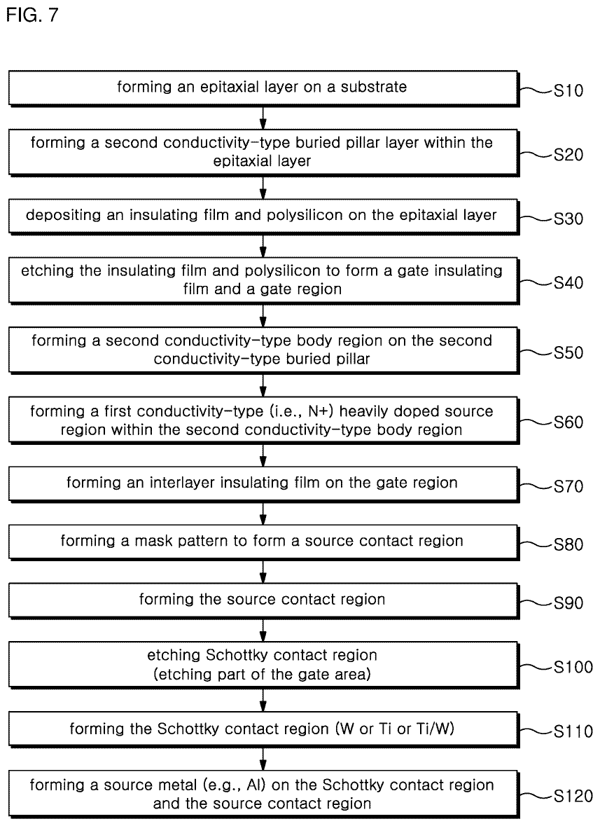

FIG. 7 illustrates a flowchart illustrating the manufacturing method of a power semiconductor device according to an example of the present disclosure.

Referring to FIG. 7, the manufacturing method of a power semiconductor device according to an example of the present disclosure includes: forming an epitaxial layer on a substrate (S10); forming a second conductivity-type buried pillar layer within the epitaxial layer (S20); depositing an insulating film and polysilicon on the epitaxial layer (S30); etching the insulating film and polysilicon to form a gate insulating film and a gate region (S40); forming a second conductivity-type body region on the second conductivity-type buried pillar (S50); forming a first conductivity-type highly doped source region within the second conductivity-type body region (S60); forming an interlayer insulating film on the gate region (S70); forming a mask pattern to form a source contact region (S80); forming the source contact region (S90); forming a mask pattern to form the Schottky contact region (S100); forming the Schottky contact region (S110); and forming a source metal layer on the Schottky contact region and the source contact region (S120).

The forming an epitaxial layer on a substrate (S10) includes forming a first conductivity-type epitaxial layer on a substrate. The first conductivity-type epitaxial layer may be formed through a plurality of epitaxial processes. The first conductivity type may be an N-type.

The forming of a second conductivity-type buried pillar layer within the epitaxial layer (S20) includes forming a second conductivity-type buried pillar layer within the first conductivity-type epitaxial layer. When explained in connection with the plurality of epitaxial layer processes, a plurality of epitaxial layers are formed on the substrate. For example, when a total of six epitaxial layers are formed, after depositing the one epitaxial layer on the substrate, a second conductivity-type ion implantation process is performed to form a second conductivity-type pillar layer within the one epitaxial layer. This process is repeated to form the first conductivity-type epitaxial layer and the second conductivity-type buried pillar layer.

The depositing of an insulating film and polysilicon on the epitaxial layer (S30) includes depositing an insulating film on the surface of the epitaxial layer and subsequently depositing polysilicon on the insulating film.

The etching of the insulating film and the polysilicon to form a gate insulating film and a gate region (S40) includes forming a mask pattern on the polysilicon, etching the remaining portions except for the mask-patterned region, and subsequently removing the mask pattern to form the gate insulating film and the gate region.

The forming of a second conductivity-type body region on the second conductivity-type buried pillar (S50) includes forming the second conductivity-type body region on the second conductivity-type buried pillar. The formation method includes performing a second conductivity-type ion implantation process between the etched gate regions, followed by a high-temperature annealing process to diffuse the ion-implanted layer. Through this diffusion, the second conductivity-type body region is formed.

The second conductivity-type body region is formed in a direction alternating with the second conductivity-type buried pillar region.

Subsequently, the forming of a first conductivity-type highly doped source region within the second conductivity-type body region (S60) includes forming a mask pattern on the second conductivity-type body region and performing a first conductivity-type ion implantation process at a high doping concentration on the patterned region. A subsequent annealing process is performed to diffuse the first conductivity-type ion-implanted layer, thereby forming the first conductivity-type highly doped source region.

Subsequently, the forming of an interlayer insulating film on the gate region (S70) is performed.

Subsequently, the forming of a mask pattern for the formation of a source contact region (S80) is performed. To form the source contact region, a mask pattern is formed to etch the previously formed interlayer insulating film. After the mask pattern is formed, an etching process is performed to secure the source contact etching region.

Subsequently, the forming of the source contact region (S90) is performed. A tungsten (W) or aluminum metal is deposited onto the etched region to form the source contact region.

Subsequently, the forming of a mask pattern to form the Schottky contact region (S100) is performed. A mask pattern process is carried out on the gate region and the source region. The mask pattern process involves depositing a mask layer on all regions except for the areas to be etched. The portion to be etched is located on part of the gate region, and etching is performed on the open areas where the mask pattern is not formed, thereby securing the region where the Schottky contact will be formed.

Subsequently, the forming of the Schottky contact region (S110) is performed. Tungsten (W), titanium (Ti), or titanium tungsten (TiW) material is deposited onto the etched region. Through this process, the Schottky contact region is formed. An interlayer insulating film is formed between the Schottky contact and the gate region, thereby creating a structure where they are electrically insulated from each other.

Subsequently, the forming of a source metal layer on the Schottky contact region and the source contact region (S120) is performed. The source metal layer may be composed of aluminum.

Subsequently, a drain electrode may be formed on the lower part of the substrate thereafter.

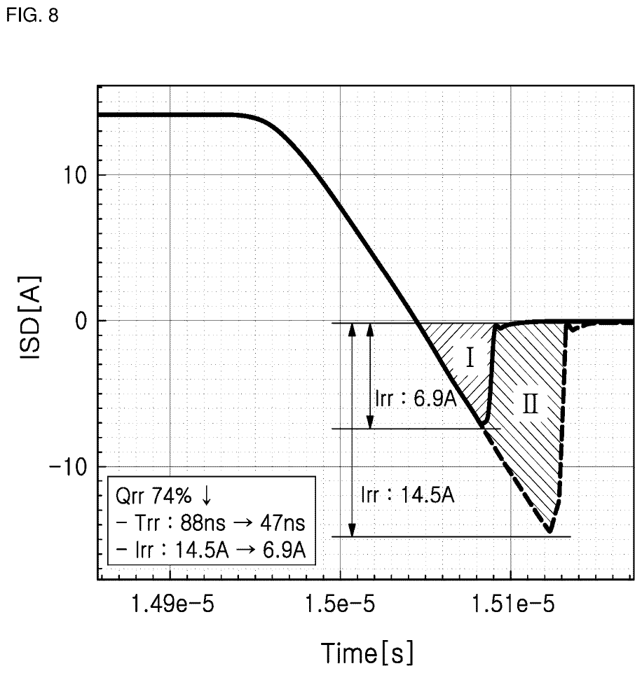

FIG. 8 illustrates a graph comparing the turn-on and turn-off states under the application of reverse bias in the power semiconductor structure of the present disclosure and the related art. Here, the related art refers to the structure where the P-type pillar and the gate poly, as described in FIG. 1, are disposed parallel to each other, a dummy gate region is formed between a plurality of gate regions, and a Schottky contact region is formed between the dummy gate regions.

Referring to FIG. 8, the reverse recovery times (Trr) of the semiconductor devices according to the related art and the present disclosure exhibit an inverse proportionality to the area of the Schottky contact. To improve the Trr characteristic, the area of the Schottky contact must be increased. However, in the related-art parallel structure, increasing the Schottky contact area reduces the N-type channel, making it impossible to secure an adequate on-resistance. To address this issue, an orthogonal cell structure is applied, enabling the improvement of Trr without on-resistance loss while maintaining the Schottky contact area of the related art.

Accordingly, the Trr value is reduced from 88 ns, in the related art, to 47 ns, in the present disclosure, thereby enabling fast turn-on and turn-off switching.

Additionally, the peak reverse recovery current (Irr) is reduced from 14.5 A to 6.9 A, indicating a reduction in the turn-on and turn-off time under reverse bias.

Additionally, the reverse recovery charge (Qrr) is reduced by approximately 74%, enabling fast switching. The reverse recovery charge refers to the total area until the current value returns to zero (0 A) after the application of reverse bias. A lower reverse recovery charge allows for faster switching. In FIG. 8, “I” represents the reverse recovery charge area of the present disclosure, while “Il” represents the reverse recovery charge area of the related art (i.e., FIG. 1).

As described above, the present disclosure provides a power semiconductor device that allows low on-resistance and reduced leakage current by implementing a cell structure in which the gate poly and pillar region are disposed orthogonally, and a Schottky contact region is formed on a portion of the gate poly line over the pillar region.

According to the present disclosure, a cell structure is implemented by arranging the gate region and the buried pillar region orthogonally to each other and forming a Schottky contact region in portion of the gate region line above the pillar region, thereby securing a low on-resistance (Rdson) and reducing leakage current. This configuration is expected to have a faster reverse recovery time and reverse recovery current compared to the conventional structure.

Furthermore, since the Schottky contact region is formed only in portion of the gate region line, the cell pitch can be reduced further compared to conventional structures.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A power semiconductor device, comprising:
a plurality of gate regions spaced apart by a predetermined interval in a first direction;
a highly doped source region of a first conductivity-type disposed between the plurality of gate regions;
a source contact region disposed on the highly doped source region of the first conductivity-type;
a plurality of buried pillar regions of a second conductivity-type spaced at a preset interval in a second direction intersecting the first direction; and
a plurality of Schottky contact regions formed at a point where the plurality of buried pillar regions of the second conductivity-type intersect with the plurality of gate regions.

2. The power semiconductor device of claim 1, further comprising:
a body region of the second conductivity-type connected to the plurality of buried pillar regions of the second conductivity-type,
wherein the plurality of buried pillar regions of the second conductivity-type are formed below the plurality of gate regions and the highly doped source region of the first conductivity-type.

3. The power semiconductor device of claim 1, wherein an epitaxial layer of the first conductivity-type is formed over the plurality of buried pillar regions of the second conductivity-type.

4. The power semiconductor device of claim 1, wherein the first direction and the second direction are orthogonal to each other.

5. The power semiconductor device of claim 1, wherein a plurality of Schottky contact regions are formed on one of the plurality of buried pillar regions of the second conductivity-type.

6. The power semiconductor device of claim 1, wherein a plurality of Schottky contact regions are formed in one of the plurality of gate regions.

7. The power semiconductor device of claim 1, wherein at least one Schottky contact region is formed in one of the plurality of gate regions.

8. The power semiconductor device of claim 5, wherein at least one of the plurality of Schottky contact regions extends in the second direction in which a buried pillar region of the second conductivity-type is not formed.

9. A power semiconductor device, comprising:
a substrate of a first conductivity-type;
an epitaxial layer of the first conductivity-type formed on the substrate of the first conductivity-type;
a plurality of buried pillar regions of a second conductivity-type formed within the epitaxial layer of the first conductivity-type;
a body region of the second conductivity-type formed at a predetermined depth from an upper surface of the epitaxial layer of the first conductivity-type and connected to the plurality of buried pillar regions of the second conductivity-type;
a highly doped source region of the first conductivity-type formed in the body region of the second conductivity-type;
a source contact region formed on the body region of the second conductivity-type;
a plurality of gate regions formed between body regions of the second conductivity-type; and
a plurality of Schottky contact regions formed in portions of the plurality of gate regions.

10. The power semiconductor device of claim 9, wherein the plurality of Schottky contact regions are formed in a region where the plurality of buried pillar regions of the second conductivity-type and the plurality of gate regions intersect.

11. The power semiconductor device of claim 9, wherein the plurality of buried pillar regions of the second conductivity-type and the plurality of gate regions intersect each other perpendicularly.

12. The power semiconductor device of claim 9, wherein the plurality of Schottky contact regions and the source contact region are connected to a source metal layer.

13. The power semiconductor device of claim 9, wherein at least one of the plurality of Schottky contact regions extends in a direction in which the plurality of buried pillar regions of the second conductivity-type are not formed.

14. The power semiconductor device of claim 9, wherein an interlayer insulating film is formed between the plurality of Schottky contact regions and the plurality of gate regions.

15. A power semiconductor device, comprising:
a substrate of a first conductivity-type;
an epitaxial layer of the first conductivity-type formed on the substrate of the first conductivity-type;
a plurality of buried pillar regions of a second conductivity-type extending in a first direction, spaced apart in a second direction, and formed within the epitaxial layer of the first conductivity-type;
a body region of a second conductivity-type formed on the plurality of buried pillar regions of the second conductivity-type;
a source region of the first conductivity-type formed within the body region of the second conductivity-type;
a source contact region formed on the body region of the first conductivity-type;
a plurality of gate regions formed on the epitaxial layer of the first conductivity-type; and
a plurality of Schottky contact regions formed in portions of the plurality of gate regions,
wherein the body region of the second conductivity-type intersects the plurality of buried pillar regions of the second conductivity-type.

16. The power semiconductor device of claim 15, wherein the plurality of buried pillar regions of the second conductivity-type simultaneously contact the body region of the second conductivity-type and the epitaxial layer of the first conductivity-type.

17. The power semiconductor device of claim 15, wherein the plurality of buried pillar regions of the second conductivity-type and the plurality of gate regions are orthogonal to each other.

18. The power semiconductor device of claim 15, wherein the plurality of buried pillar regions of the second conductivity-type intersect perpendicularly with the body region of the second conductivity-type.

19. The power semiconductor device of claim 16, wherein at least one of the plurality of Schottky contact regions extends in the first and second directions and contacts the epitaxial layer of the first conductivity-type.

20. The power semiconductor device of claim 15, wherein a width of the body region of the second conductivity-type is less than a width of a buried pillar region of the second conductivity-type.
